(19) United States
(12) Patent Application Publication
(10) Pub. No.: US 2026/0352243 A1
(43) Pub. Date: Nov. 5, 2026

(54) TRANSMISSION CIRCUIT AND COMMUNICATION DEVICE INCLUDING THE SAME

(71) Applicant: Murata Manufacturing Co., Ltd., Kyoto (JP)

(72) Inventors: Kenji TAHARA, Kyoto (JP); Kae YAMAMOTO, Kyoto (JP)

(73) Assignee: Murata Manufacturing Co., Ltd., Kyoto (JP)

(21) Appl. No.: 19/712,058

(22) Filed: Jun. 18, 2026

Related U.S. Application Data
(63) Continuation of application No. PCT/JP2025/003248, filed on Jan. 31, 2025.

(30) Foreign Application Priority Data
Feb. 20, 2024 (JP) 2024-023350

(51) Int. Cl. H04B 1/04; H03F 1/02; H03F 3/24

(52) U.S. Cl. CPC H04B 1/0483; H03F 1/0288; H03F 3/245; H03F 2200/451; H04B 2001/045

(57) ABSTRACT

A transmission circuit includes an input terminal, an output terminal, first and second amplifier circuits, control circuitry, and an output line. The first amplifier circuit is a Doherty amplifier that includes a carrier amplifier, a peaking amplifier, and a phase shift line. The second amplifier circuit includes first and second amplifiers and a hybrid coupler having first to fourth lines connected in an annular shape. An output end of the amplifier is connected to a first connection node between first and second lines An output end of the second amplifier is connected to a second connection node between first and third lines. An output end of the peaking amplifier and the output line are connected to a third connection node between the second and the fourth lines. The control circuitry selectively switches drive states of the amplifiers based on a power level of a received radio frequency signal.

### CROSS-REFERENCE TO RELATED APPLICATIONS

This application is a continuation application of International Application No. PCT/JP2025/003248, filed on Jan. 31, 2025, which claims the benefit of priority to Japanese Patent Application No. 2024-023350, filed on Feb. 20, 2024. The entire contents of each of these applications are incorporated herein by reference.

### TECHNICAL FIELD

The present disclosure relates to a transmission circuit and a communication device including the same, and more particularly to a technique for improving the efficiency of a transmission circuit that includes an amplifier.

### BACKGROUND ART

An amplifier circuit including a first differential amplifier (a carrier amplifier) and a second differential amplifier (a peaking amplifier) that amplify signals distributed from an input signal, and transformers (a first transformer and a second transformer) that are separately provided for the differential amplifiers is disclosed in Japanese Unexamined Patent Application Publication No. 2018-137566 (Patent Document 1). The first differential amplifier operates in a region in which the power level of the input signal is equal to or more than a first level, and the second differential amplifier operates in a region in which the power level of the input signal is equal to or more than a second level higher than the first level. The first transformer and the second transformer receive and synthesize respective signals that are output from the first differential amplifier and the second differential amplifier, and the synthesized output signal is output to a load.

### CITATION LIST

### Patent Document

Patent Document 1: Japanese Unexamined Patent Application Publication No. 2018-137566

### SUMMARY

A transmission circuit according to the present disclosure amplifies and transmits a radio frequency signal to a radiating element. The transmission circuit includes an input terminal that receives a radio frequency signal, a first output terminal for connection to the radiating element, a first amplifier circuit, a second amplifier circuit, and a first output line. The first amplifier circuit and the second amplifier circuit amplify the radio frequency signal that is received by the input terminal. Through the first output line, an output signal from the first amplifier circuit is transmitted to the first output terminal. The first amplifier circuit is a Doherty amplifier that includes a first carrier amplifier, a first peaking amplifier, and a first phase shift line that is connected between an output end of the first carrier amplifier and an output end of the first peaking amplifier. The second amplifier circuit includes a first amplifier, a second amplifier, and a hybrid coupler. The hybrid coupler includes a first line, a second line, a third line, and a fourth line that are connected in an annular shape. An output end of the first amplifier is connected to a first connection node between the first line and the second line. An output end of the second amplifier is connected to a second connection node between the first line and the third line. The output end of the first peaking amplifier and the first output line are connected to a third connection node between the second line and the fourth line. Control circuitry is configured to switch drive states of the first peaking amplifier, the first amplifier, and the second amplifier based on a power level of a radio frequency signal received at the input terminal.

### BRIEF DESCRIPTION OF DRAWINGS

FIG. 1 schematically illustrates the structure of a communication device that uses a transmission circuit according to a first embodiment.

FIG. 2 illustrates the detailed structure of a power amplifier circuit in FIG. 1.

FIG. 3 is a diagram for describing a circuit structure in the case where a radio frequency signal is transmitted from an output terminal T1.

FIG. 4 is a diagram for describing a circuit structure in the case where a radio frequency signal is transmitted from an output terminal T2.

FIG. 5 is a diagram for describing a relationship between the efficiency and output power of the power amplifier circuit in FIG. 1.

FIG. 6 is a diagram for describing impedance in a region RG1 in FIG. 5.

FIG. 7 is a diagram for describing impedance in a region RG2 in FIG. 5.

FIG. 8 is a diagram for describing impedance in a region RG3 in FIG. 5.

FIG. 9 is a first diagram for describing the influence of a load variation at maximum power output.

FIG. 10 is a second diagram for describing the influence of the load variation at the maximum power output.

FIG. 11 is a first diagram for describing the influence of the load variation at 6 dB backoff.

FIG. 12 is a second diagram for describing the influence of the load variation at the 6 dB backoff.

FIG. 13 is a diagram for describing the structure of a power amplifier circuit that is used for a transmission circuit according to a second embodiment and the impedance in the region RG1.

FIG. 14 is a diagram for describing the impedance in the region RG2 in the power amplifier circuit in FIG. 13.

FIG. 15 is a diagram for describing the impedance in the region RG3 in the power amplifier circuit in FIG. 13.

FIG. 16 illustrates the structure of a power amplifier circuit that uses a transmission circuit according to a third embodiment.

### DESCRIPTION OF EMBODIMENTS

The use of digital envelope tracking (ET) for the power supply voltage of a power amplifier circuit that has a structure as disclosed in Patent Document 1 improves the efficiency of a backoff region from a high-output region in which the carrier amplifier and the peaking amplifier enter a drive state to a low-output state in which only the carrier amplifier enters the drive state.

As for the structure of a standard Doherty amplifier and Patent Document 1, a backoff amount of 6 dB can be typically achieved. However, the inventors have realized that the backoff amount required for a power amplifier circuit can change depending on, for example, a modulation method, the set voltage of a digital ET, and/or a target frequency band width. For this reason, a backoff amount of more than 6 dB may be needed depending on a specification required for a device that uses a power amplifier circuit in some cases.

The present disclosure is directed to providing a power amplifier circuit that enables a backoff amount of 6 dB or more to be achieved.

A power amplifier circuit that is included in a transmission circuit according to the present disclosure includes a first amplifier circuit that includes a Doherty amplifier, and a second amplifier circuit that includes two amplifiers and a hybrid coupler and outputs, from an output terminal, a signal acquired by synthesizing output signals from the two amplifier circuits. As for the power amplifier circuit, operating states of a peaking amplifier in the first amplifier circuit and the two amplifiers in the second amplifier circuit are switched depending on the power level of an input signal. The impedance of the amplifiers that are operating can be changed depending on the operating states of the amplifiers, and accordingly, a backoff amount can be set in multiple stages. This enables the transmission circuit to achieve a backoff amount of 6 dB or more.

Embodiments of the present disclosure will hereinafter be described in detail with reference to the drawings. Portions like or corresponding to each other in the drawings are designated by using like reference signs, and the description thereof is not repeated.

### First Embodiment

### Entire Structure of Communication Device

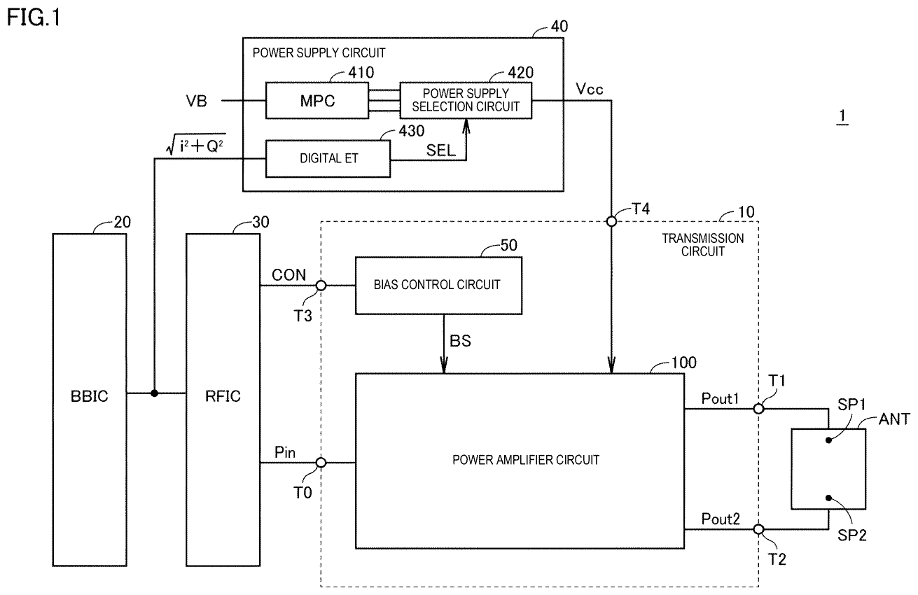

FIG. 1 schematically illustrates the structure of a communication device 1 that uses a transmission circuit 10 according to an embodiment. Examples of the communication device 1 include a cellular phone, a smartphone, a mobile terminal such as a tablet, and a personal computer that has a communication function.

Referring to FIG. 1, the communication device 1 includes an antenna ANT, the transmission circuit 10, a BBIC (Baseband Integrated Circuit) 20 that is included in a baseband signal processing circuit, a RFIC (Radio Frequency Integrated Circuit) 30, and a power supply circuit 40. The transmission circuit 10 includes input terminals T0, T3, and T4, output terminals T1 and T2, a bias control circuit 50, and a power amplifier circuit 100. Roughly, the communication device 1 up-converts an intermediate frequency (IF) signal that is transmitted from the BBIC 20 into a radio frequency (RF) signal by using the RFIC 30, amplifies the radio frequency signal by using the power amplifier circuit 100, and radiates the radio frequency signal via the antenna ANT.

The RFIC 30 is an example of a signal processing circuit that processes a radio frequency signal. The RFIC 30 up-converts the intermediate frequency signal that is transmitted from the BBIC 20 into the radio frequency signal and outputs the generated radio frequency signal to the transmission circuit 10 via the input terminal T0.

The bias control circuit 50 receives a control signal CON from the RFIC 30 via the input terminal T3. The bias control circuit 50 generates a bias signal BS for controlling the magnitude of the bias current of an amplifier that is included in the power amplifier circuit 100 and a supply timing, based on the control signal CON and outputs the bias signal BS to the power amplifier circuit 100.

The power amplifier circuit 100 amplifies an input signal Pin that is received from the RFIC 30 via the input terminal T0 and generates output signals Pout1 and Pout2.

An example of the antenna ANT is a patch antenna that has a flat plate shape. The output terminal T1 of the transmission circuit 10 is connected to a feed point SP1 of the antenna ANT. The output terminal T2 of the transmission circuit 10 is connected to a feed point SP2 of the antenna ANT. The antenna ANT radiates, as a radio wave, the output signals Pout1 and Pout2 that are radio frequency signals output from the transmission circuit 10.

The power supply circuit 40 is an example of a so-called digital tracker and is capable of supplying power supply voltage Vcc at different voltage levels to the power amplifier circuit 100. The power supply circuit 40 includes a multilevel power converter (MPC) 410, a power supply selection circuit 420, and a digital envelope tracker (a digital ET) 430.

The MPC 410 includes multiple DC/DC converters. The MPC 410 converts a battery voltage VB that is supplied from an external battery into voltages at multiple different voltage levels and supplies the voltages to the power supply selection circuit 420.

The digital ET 430 receives an I/Q wave signal of a transmission signal from the BBIC 20 and tracks the envelope of the transmission signal in a digital ET mode. The digital ET 430 generates a selection signal SEL corresponding to the voltage level of the envelope of the transmission signal and outputs the selection signal SEL to the power supply selection circuit 420.

The power supply selection circuit 420 selects a voltage corresponding to the selection signal SEL from the voltages at the multiple voltage levels that are supplied from the MPC 410 and supplies, as the power supply voltage Vcc, the voltage to the power amplifier circuit 100 via the input terminal T4.

### Detailed Structure of Power Amplifier Circuit

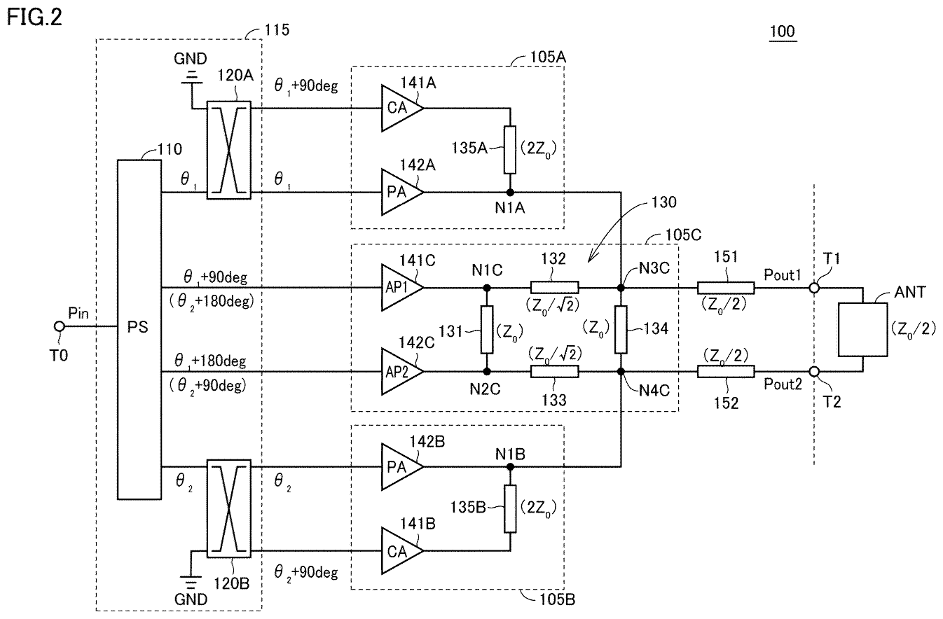

The detailed structure of the power amplifier circuit 100 in the transmission circuit 10 will now be described with reference to FIG. 2.

The power amplifier circuit 100 includes a branch circuit 115, amplifier circuits 105A, 105B, and 105C, and output lines 151 and 152. The amplifier circuit 105A includes a carrier amplifier 141A, a peaking amplifier 142A, and a phase shift line 135A. The phase shift line 135A is connected between an output end of the carrier amplifier 141A and an output end (a connection node N1A) of the peaking amplifier 142A. The phase shift line 135A has an electrical length corresponding to the quarter wavelength of the center frequency of the frequency band (band A) of a radio frequency signal that is output by using the amplifier circuit 105A.

The amplifier circuit 105B includes a carrier amplifier 141B, a peaking amplifier 142B, and a phase shift line 135B. The phase shift line 135B is connected between an output end of the carrier amplifier 141B and an output end (a connection node N1B) of the peaking amplifier 142B. The phase shift line 135B has an electrical length corresponding to the quarter wavelength of the center frequency of the frequency band (band B) of a radio frequency signal that is output using the amplifier circuit 105B.

The amplifier circuit 105C includes amplifiers 141C and 142C and a hybrid coupler 130. The hybrid coupler 130 includes phase shift lines 131 to 134 that are connected in an annular shape. The phase shift lines 131 to 134 of the hybrid coupler 130 have the electrical length of the quarter wavelength of the center frequency of a frequency band that is defined by the band A and the band B. An output end of the amplifier 141C is connected to a connection node N1C between the phase shift line 131 and the phase shift line 132. An output end of the amplifier 142C is connected to a connection node N2C between the phase shift line 131 and the phase shift line 133.

The output end of the peaking amplifier 142A of the amplifier circuit 105A is connected to a connection node N3C between the phase shift line 132 and the phase shift line 134. The output line 151 is connected between the connection node N3C and the output terminal T1. The output line 151 has an electrical length corresponding to the quarter wavelength of the center frequency of the band A.

The output end of the peaking amplifier 142B of the amplifier circuit 105B is connected to a connection node N4C between the phase shift line 133 and the phase shift line 134. The output line 152 is connected between the connection node N4C and the output terminal T2. The output line 152 has an electrical length corresponding to the quarter wavelength of the center frequency of the band B.

The branch circuit 115 includes a phase shift circuit (PS) 110 and hybrid couplers 120A and 120B. The phase shift circuit 110 applies a phase difference to the input signal Pin that is received by the input terminal T0 from the RFIC 30 and branches into multiple paths (a first path to a fourth path).

Through the first path, a radio frequency signal is transmitted to the amplifier circuit 105A via the hybrid coupler 120A. Through the second path and the third path, radio frequency signals are transmitted to the amplifier circuit 105C. Through the fourth path, a radio frequency signal is transmitted to the amplifier circuit 105B via the hybrid coupler 120B. Each of the hybrid couplers 120A and 120B causes a signal from the phase shift circuit 110 to branch into two paths and apply a phase difference of 90° to two branched signals.

A first input end of the hybrid coupler 120A is connected to the first path. A second input end of the hybrid coupler 120A is connected to a ground potential GND. A first output end of the hybrid coupler 120A is connected to the carrier amplifier 141A of the amplifier circuit 105A. A second output end of the hybrid coupler 120A is connected to the peaking amplifier 142A of the amplifier circuit 105A. A signal that has a phase shifted by 90° relative to the phase θ₁ of a signal that is supplied to the peaking amplifier 142A is supplied to the carrier amplifier 141A.

A first input end of the hybrid coupler 120B is connected to the fourth path. A second input end of the hybrid coupler 120B is connected to the ground potential GND. A first output end of the hybrid coupler 120B is connected to the carrier amplifier 141B of the amplifier circuit 105B. A second output end of the hybrid coupler 120B is connected to the peaking amplifier 142B of the amplifier circuit 105B. A signal that has a phase shifted by 90° relative to the phase θ₂ of a signal that is supplied to the peaking amplifier 142B is supplied to the carrier amplifier 141B.

The second path is connected to the amplifier 141C of the amplifier circuit 105C. The third path is connected to the amplifier 142C of the amplifier circuit 105C. In the case where a radio frequency signal is supplied to the first path, that is, the amplifier circuit 105A, a signal that has a phase shifted by 90° relative to the phase θ₁ of the signal that is supplied to the peaking amplifier 142A is supplied to the amplifier 141C. A signal that has a phase shifted by 180° relative to the phase θ₁ of the signal that is supplied to the peaking amplifier 142A is supplied to the amplifier 142C.

In the case where a radio frequency signal is supplied to the fourth path, that is, the amplifier circuit 105B, a signal that has a phase shifted by 180° relative to the phase θ₂ of the signal that is supplied to the peaking amplifier 142B is supplied to the amplifier 141C. A signal that has a phase shifted by 90° relative to the phase θ₂ of the signal that is supplied to the peaking amplifier 142B is supplied to the amplifier 142C.

In the case where the impedance of the antenna ANT is Z₀/2, the impedance of the output lines 151 and 152 is set at Z₀/2, and the impedance of the phase shift lines 135A and 135B in the amplifier circuits 105A and 105B is set at 2Z₀. The impedance of the phase shift lines 131 and 134 in the hybrid coupler 130 of the amplifier circuit 105C is set at Z₀, and the impedance of the phase shift lines 132 and 133 is set at Z₀/√2.

### Dual-Band Compatible)

In recent years, communication that uses signals in a sub-terahertz frequency band (for example, 122.25 GHz to 174.8 GHz) has been considered. The center frequency of the frequency band is 148.525 GHz, and accordingly, a fractional band width is (174.8−122.25)×100/148.525=35.4[%], which is much higher than a typical fractional band width of several tens of percent. Accordingly, it is difficult to achieve the entire target frequency band described above by using an amplifier circuit alone.

In such a case, it is thought that the target frequency band is divided into two or more bands, and amplifier circuits to be used are switched by using a switch depending on the frequency band. As for the signals in the sub-terahertz frequency band, however, transmission loss due to switching is greater than that of signals in a lower frequency band, and accordingly, a switching method performed by using the switch described above may cause a decrease in the efficiency of the amplifier circuits.

In view of this, the power amplifier circuit 100 in the transmission circuit 10 according to the first embodiment has a structure in which the amplifier circuits 105A and 105B corresponding to respective two frequency bands are connected by using the hybrid coupler 130 of the amplifier circuit 105C that is shared in the frequency bands. With this structure, one of the amplifier circuits 105A and 105B corresponding to the frequency band of a radio frequency signal to be transmitted is driven, and the amplifier circuit corresponding to the other frequency band is stopped. This enables radio frequency signals in the two frequency bands to be switched and transmitted without using a switch that causes a great loss.

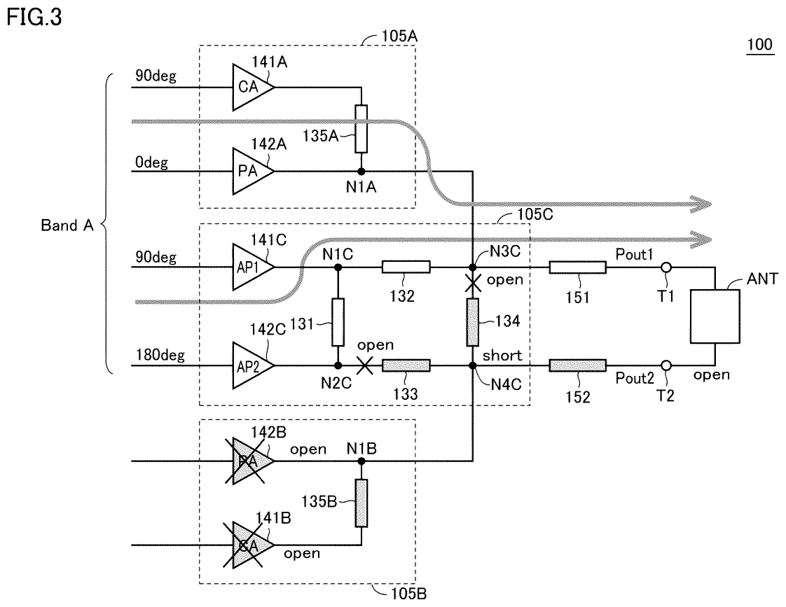

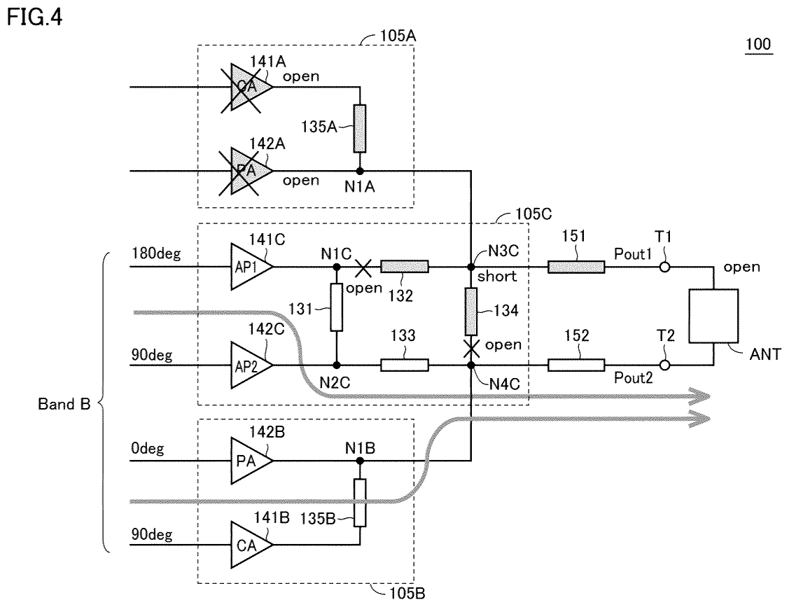

FIG. 3 and FIG. 4 illustrate circuit structures in the case where radio frequency signals in two different frequency bands are switched. FIG. 3 illustrates the case where a radio frequency signal in the band A (for example, 122.25 GHz to 148.5 GHz) is transmitted from the output terminal T1. FIG. 4 illustrates the case where a radio frequency signal in the band B (for example, 151.5 GHz to 174.8 GHz) is transmitted from the output terminal T2.

Referring to FIG. 3, in the case where a radio frequency signal in the band A is transmitted from the output terminal T1, the amplifier circuits 105A and 105C enter a drive state, and the amplifier circuit 105B enters a non-drive state. Consequently, the impedance of the connection node N4C in the hybrid coupler 130 becomes short. As a result, impedance when the phase shift line 133 is viewed from the connection node N2C, and impedance when the phase shift line 134 is viewed from the connection node N3C become open. Accordingly, a radio frequency signal that is supplied to the amplifier circuit 105C is not transmitted to the output terminal T2.

Consequently, the amplifier circuit 105C functions as a Doherty amplifier with the amplifier 142C serving as a carrier amplifier and the amplifier 141C serving as a peaking amplifier. When a signal that has a phase shifted by 90° relative to the phase of a radio frequency signal that is supplied to the amplifier circuit 105A is supplied to the amplifier circuit 105C, the radio frequency signal that is supplied to the amplifier circuit 105A and the radio frequency signal that is supplied to the amplifier circuit 105C are synthesized with the same phase at the connection node N3C. The synthesized radio frequency signal passes through the output line 151 and is output to the antenna ANT via the output terminal T1.

In the case where a radio frequency signal in the band B is transmitted from the output terminal T2, as illustrated in FIG. 4, the amplifier circuits 105B and 105C enter the drive state, and the amplifier circuit 105C enters the non-drive state. Consequently, the impedance of the connection node N3C in the hybrid coupler 130 becomes short. As a result, impedance when the phase shift line 132 is viewed from the connection node N1C and impedance when the phase shift line 134 is viewed from the connection node N4C become open. Accordingly, the radio frequency signal that is supplied to the amplifier circuit 105C is not transmitted to the output terminal T1.

Consequently, the amplifier circuit 105C functions as a Doherty amplifier with the amplifier 141C serving as a carrier amplifier and the amplifier 142C serving as a peaking amplifier. When a signal that has a phase shifted by 90° relative to the phase of a radio frequency signal that is supplied to the amplifier circuit 105B is supplied to the amplifier circuit 105C, the radio frequency signal that is supplied to the amplifier circuit 105B and the radio frequency signal that is supplied to the amplifier circuit 105C are synthesized with the same phase at the connection node N4C. The synthesized radio frequency signal passes through the output line 152 and is output to the antenna ANT via the output terminal T2.

The power amplifier circuit 100 is capable of switching and transmitting radio frequency signals in two frequency bands without using a switch as described above.

### Increase in Backoff Amount

A signal in a frequency band higher than a conventionally used frequency band such as the sub-terahertz frequency band described above tends to attenuate unlike a signal in a low frequency band. For this reason, a power amplifier circuit is to track a power supply voltage in response to a change in an input signal in a wide modulation band width. In order to realize this, a digital ET mode in which power supply voltages that have multiple discrete different voltage levels are set within one frame is typically used.

Characteristics of a typical amplifier include the tendency of a decrease in the efficiency as the input signal decreases. For this reason, when the power level of the input signal decreases in the digital ET mode, the efficiency of the amplifier can decrease. The characteristics of the amplifier, however, include the tendency of an increase in the efficiency as load impedance increases. A Doherty amplifier is known as a structure for increasing the efficiency of amplification by using the characteristics.

Roughly, a Doherty amplifier has a structure in which a carrier amplifier and a peaking amplifier are connected in parallel between an input terminal and an output terminal, and a phase shifter that functions as an impedance inverter is disposed between the carrier amplifier and a synthesization or combining node. In the case where output power is low, only the carrier amplifier operates, and when the output power exceeds a predetermined value, both of the carrier amplifier and the peaking amplifier operate. When the peaking amplifier is not driven, the load impedance of the carrier amplifier increases. For this reason, whether the peaking amplifier is driven or is not driven is switched in response to a change in the power level of the input signal in the digital ET mode, and consequently, the Doherty amplifier can achieve a backoff amount of about 6 dB.

However, the backoff amount for a power amplifier circuit can change depending on, for example, the modulation method, the set voltage of the digital ET, and/or the target band width. For this reason, in some cases, a backoff amount of more than 6 dB is needed depending on a specification for a device that uses a power amplifier circuit.

In view of this, as for the power amplifier circuit 100 according to the first embodiment, two Doherty amplifiers are connected by a phase shift line, peaking amplifiers in the Doherty amplifiers are not driven as the power level of the input signal decreases, and a carrier amplifier of one of the Doherty amplifiers is not driven in the case where the power level of the input signal further decreases. With this structure, a backoff amount of 6 dB can be achieved when the peaking amplifiers are stopped, and a backoff amount of 6 dB can be additionally achieved when one of the carrier amplifiers is stopped. Accordingly, the power amplifier circuit 100 can achieve a backoff amount of 12 dB in total.

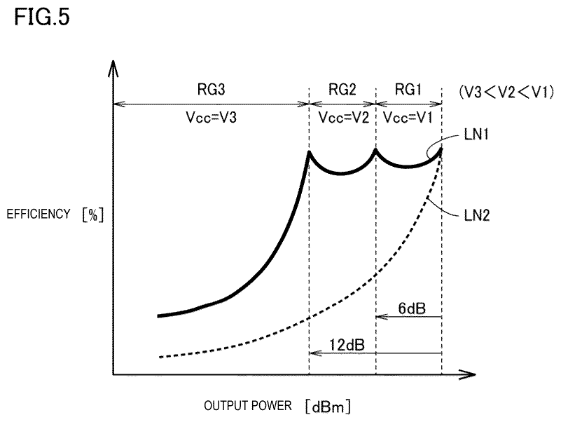

FIG. 5 is a diagram for describing a relationship between the efficiency and output power regarding the power amplifier circuit 100 according to the first embodiment. In FIG. 5, the horizontal axis represents the power level of an output signal Pout from the power amplifier circuit 100, and the vertical axis represents the efficiency of the power amplifier circuit 100. A solid line LN1 represents the efficiency in the case of the power amplifier circuit 100, and a dashed line LN2 represents the efficiency in the case where a class AB amplifier that is capable of outputting the same maximum power as the power amplifier circuit 100 is used.

As for the power amplifier circuit 100, the power supply voltage Vcc from the power supply circuit 40 is switched in three stages depending on the power level of the input signal Pin. In the region RG1 that is a high-output region, the power supply voltage Vcc is set at V1. In the region RG2 that is an intermediate-output region, the power supply voltage Vcc is set at V2 lower than V1 (V1>V2). In the region RG3 that is a low-output region, the power supply voltage Vcc is set at V3 lower than V2 (V2>V3).

In the region RG1, great power is needed, and accordingly, the carrier amplifiers and the peaking amplifiers of the Doherty amplifiers enter the drive state. In the region RG2, the peaking amplifiers of the Doherty amplifiers enter the non-drive state, and only the carrier amplifiers are driven. In the region RG3, the carrier amplifier of one of the Doherty amplifiers enters the non-drive state.

Referring to FIG. 5, in the case where the class AB amplifier is used, and in the case where the output power is maximum power P0, the efficiency is maximized, and the efficiency gradually decreases as the output power decreases (the dashed line LN2).

As for the power amplifier circuit 100, in the region RG1, the carrier amplifiers and the peaking amplifiers of the two Doherty amplifiers operate in parallel, and the efficiency is improved unlike the case of the class AB amplifier. In the region RG2, the peaking amplifiers of the Doherty amplifiers are stopped, and consequently, the load impedance of the carrier amplifiers in the Doherty amplifiers increases. This enables the efficiency of the carrier amplifiers to increase. In the region RG3, the carrier amplifier of one of the Doherty amplifiers is stopped, and accordingly, the load impedance of the carrier amplifier that is finally driven increases. Accordingly, the efficiency of the carrier amplifier increases. This enables a backoff amount of 12 dB to be achieved (the solid line LN1).

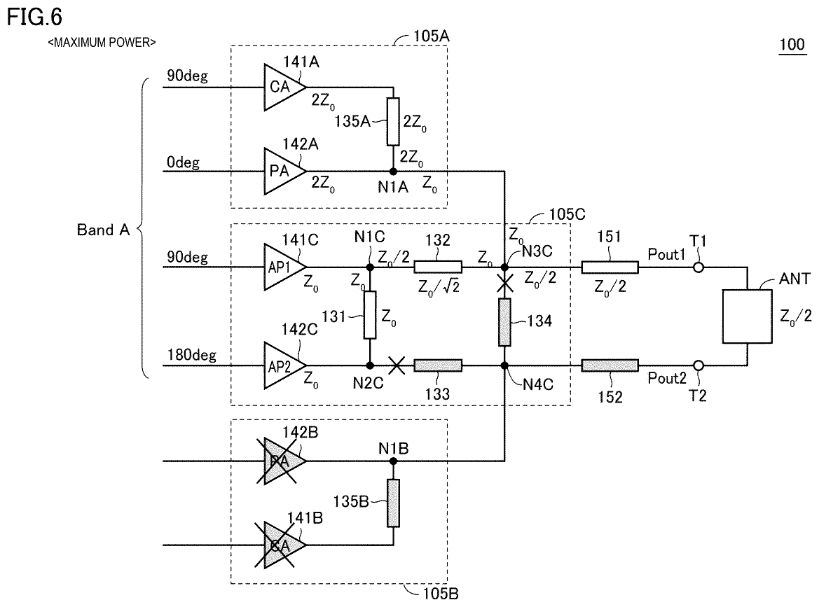

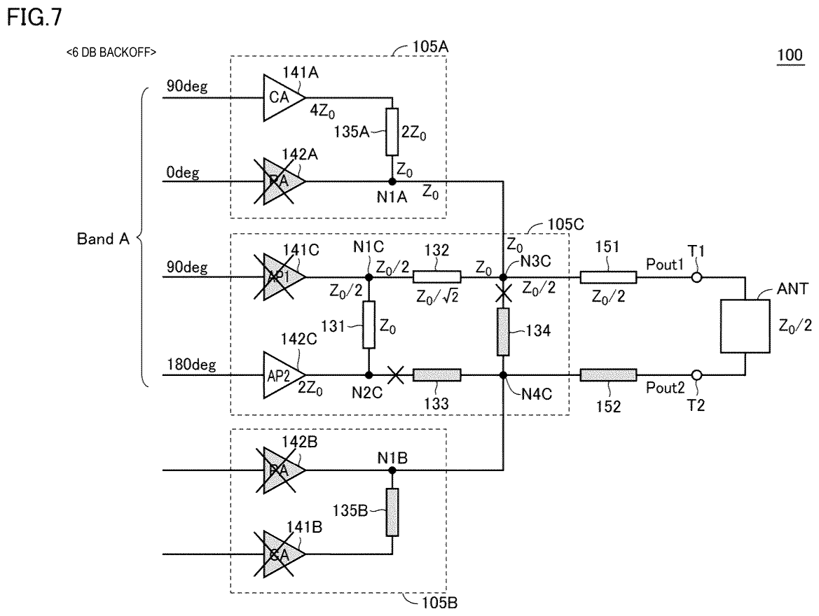

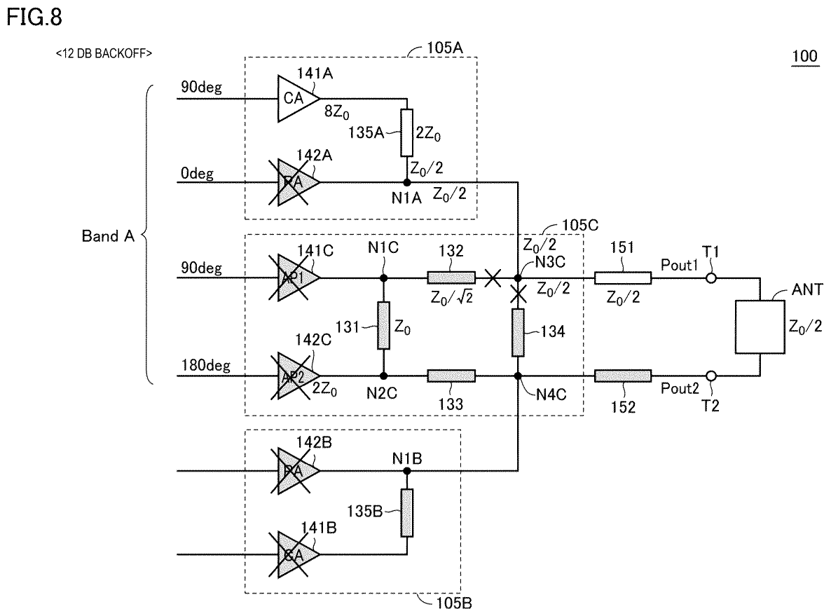

Impedance in the power amplifier circuit 100 that is in an operating state corresponding to each region in FIG. 5 will now be described with reference to FIG. 6 to FIG. 8. FIG. 6 is a diagram for describing the impedance in the power amplifier circuit 100 in the region RG1 in FIG. 5. FIG. 7 is a diagram for describing the impedance in the power amplifier circuit 100 in the region RG2 in FIG. 5. FIG. 8 is a diagram for describing the impedance in the power amplifier circuit 100 in the region RG3 in FIG. 5.

With reference to FIG. 6 to FIG. 8, the case where a radio frequency signal in the frequency band of the band A is output, that is, the case where the amplifier circuit 105A and the amplifier circuit 105C are driven will be described by way of example. In this case, the impedance when the phase shift line 133 is viewed from the connection node N2C and the impedance when the phase shift line 134 is viewed from the connection node N3C become open as described above.

In the case where the load impedance of the antenna ANT is Z₀/2, the impedance of the output line 151 is Z₀/2, and accordingly, the impedance when a load is viewed from the connection node N3C is Z₀/2.

Since the impedance when the phase shift line 134 is viewed from the connection node N3C is open, impedance in a branch path from the connection node N3C to the amplifier circuit 105A and a branch path from the connection node N3C to the phase shift line 132 is Z₀.

As for the amplifier circuit 105A, the impedance of a branch path from the connection node N1A to the phase shift line 135A and a branch path from the connection node N1A to the peaking amplifier 142A is 2Z₀. The impedance of the phase shift line 135A is 2Z₀, and accordingly, the impedance of the carrier amplifier 141A is 2Z₀.

As for the amplifier circuit 105C, the impedance of the phase shift line 132 is Z₀/√2, and accordingly, impedance when the load is viewed from the connection node N1C is Z₀/2. The impedance of the phase shift line 131 is Z₀, and accordingly, impedance when the load is viewed from output ends of the amplifier 141C and the amplifier 142C is Z₀.

In the case where the sizes of amplifiers are equal to each other, an amplifier that has a lower impedance is typically capable of outputting greater power than an amplifier that has a higher impedance. For this reason, the sizes of the amplifiers 141C and 142C of the amplifier circuit 105C can be smaller than the sizes of the amplifier circuits 105A and 105B.

In the case of the region RG2 in FIG. 7, the peaking amplifier 142A in the amplifier circuit 105A and the amplifier 141C in the amplifier circuit 105C enter the non-drive state. For this reason, as for the amplifier circuit 105A, the impedance in the branch path from the connection node N1A to the phase shift line 135A is Z₀. As a result, impedance when the load is viewed from the output end of the carrier amplifier 141A is 4Z₀, and the impedance is twice that in the case of the region RG1 in FIG. 6.

Similarly, impedance in a branch path from the connection node N1C to the phase shift line 131 is Z₀/2. Consequently, the impedance when viewed from the output end of the amplifier 142C is 2Z₀, and the impedance is twice that in the case of the region RG1 in FIG. 6.

As for the Doherty amplifiers that are included in the amplifier circuit 105C and the amplifier circuit 105A, in the region RG2, the number of the amplifiers is halved in comparison with the operating state in the region RG1, and the load impedance is doubled. Accordingly, a backoff amount of 6 dB can be achieved.

In the case of the region RG3 in FIG. 8, the amplifier 142C of the amplifier circuit 105C enters the non-drive state, and accordingly, impedance when the phase shift line 132 is viewed from the connection node N3C is open. For this reason, the impedance in the branch path from the connection node N3C to the amplifier circuit 105A is Z₀/2. As for the amplifier circuit 105A, the peaking amplifier 142A enters the non-drive state, and accordingly, the impedance when the load is viewed from the output end of the carrier amplifier 141A is 8Z₀. That is, the impedance is twice that in the case of the region RG2 in FIG. 7.

In the region RG3, the number of the amplifiers is halved in comparison with the operating state in the region RG2, and the load impedance is doubled. Accordingly, a backoff amount of 6 dB can be additionally achieved. Accordingly, a backoff amount of 12 dB can be achieved unlike the operating state in the region RG1.

In the case where a radio frequency signal in the band B is output from the output terminal T2, the amplifier circuit 105A enters the non-drive state. Accordingly, as for the amplifier circuit 105C, the impedance when the phase shift line 132 is viewed from the connection node N1C and the impedance when the phase shift line 134 is viewed from the connection node N4C are open. Consequently, the amplifier circuit 105C operates as a Doherty amplifier with the amplifier 141C serving as a carrier amplifier, and the amplifier 142C serving as a peaking amplifier. Also in this case, a backoff amount of 6 dB can be accordingly achieved in an operating state in which the peaking amplifier 142B of the amplifier circuit 105B and the amplifier 142C of the amplifier circuit 105C enter the non-drive state. In addition, the amplifier 141C of the amplifier circuit 105C enters the non-drive state, and consequently, a backoff amount of 6 dB can be additionally achieved.

### Improvement in Robustness Against Load Variation

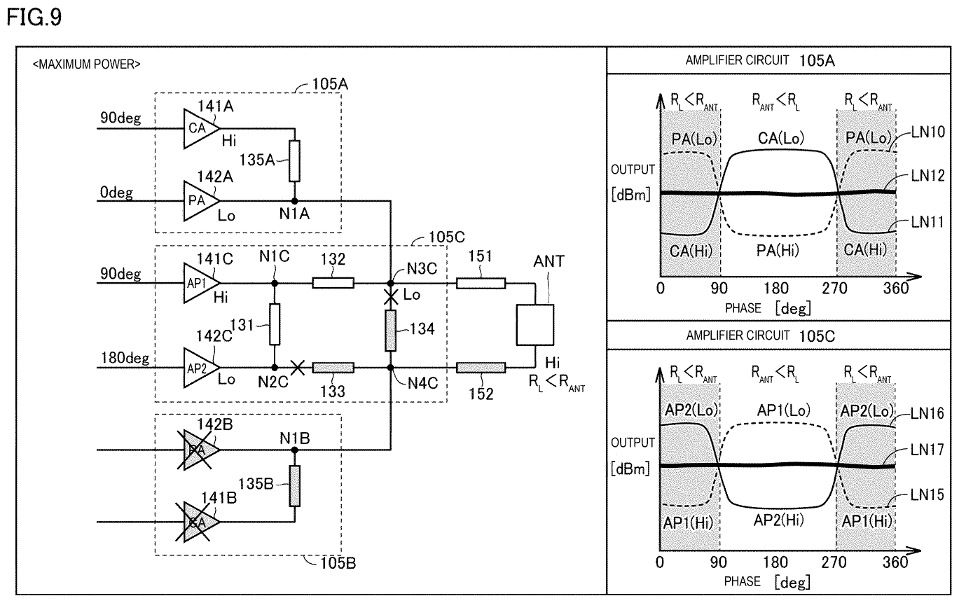

Robustness in the case where a load variation occurs in the power amplifier circuit 100 will now be described with reference to FIG. 9 to FIG. 12. Also with reference to FIG. 9 to FIG. 12, the case where a signal in the frequency band of the band A is output will be described by way of example.

In the case where a radio frequency signal is output from the output terminal T1, as illustrated in FIG. 6, the amplifier circuit 105B enters the non-drive state, and consequently, an output end of a Doherty amplifier that is implemented by the amplifier circuit 105B is connected to an output end of the amplifier circuit 105A at the connection node N3C with the phase shift line 132 interposed therebetween.

The phase shift line 132 has the electrical length of the quarter wavelength of the center frequency of the frequency band that is defined by the band A and the band B. For this reason, in the case where the load impedance R_{ANT} of the antenna ANT changes from the characteristic impedance R_{L}, the direction of the load variation at the connection node N1A that coincides with the output end of the amplifier circuit 105A and the direction of the load variation at the connection node N1C that coincides with the output end of the amplifier circuit 105C are opposite each other, due to the phase shift line 132. Consequently, as for a synthesized signal of an output signal from the amplifier circuit 105A and an output signal of the amplifier circuit 105C, variations in the output power are canceled out, and accordingly, the variations in the output power due to the load variation are reduced, that is, the robustness against the load variation is improved.

### (a) at Maximum Power Output

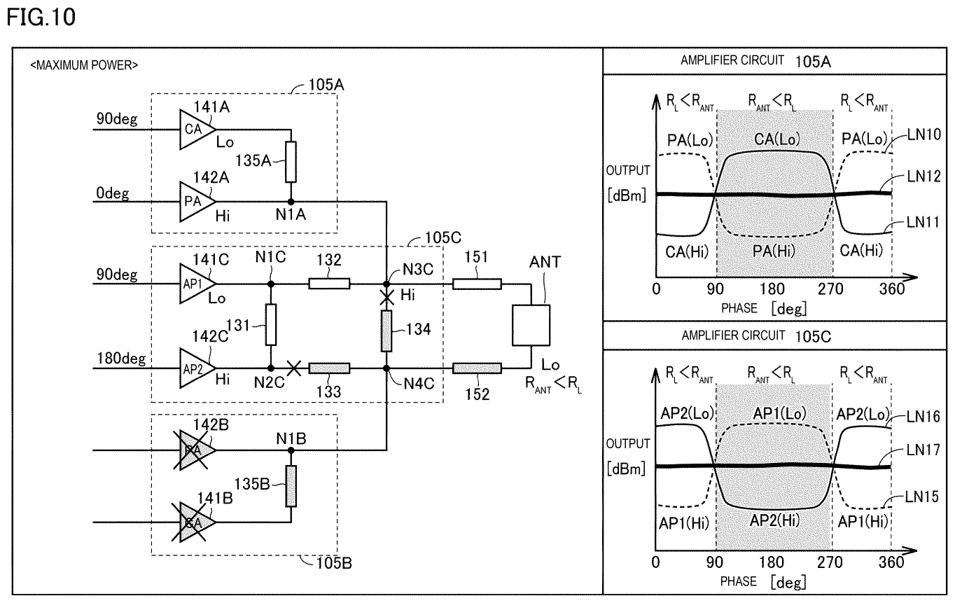

FIG. 9 and FIG. 10 are diagrams for describing the influence of the load variation at maximum power output, that is, in the case where all of the amplifiers that are included in the amplifier circuits 105A and 105C enter the drive state. FIG. 9 is the diagram for describing an output state regarding the amplifiers in the case where the load impedance R_{ANT} of the antenna ANT exceeds the characteristic impedance R_{L} (R_{L}<R_{ANT}). FIG. 10 is the diagram for describing the output state regarding the amplifiers in the case where the load impedance R_{ANT} of the antenna ANT is less than the characteristic impedance R_{L} (R_{ANT}<R_{L}).

In FIG. 9 and FIG. 10 to FIG. 12, the direction of a variation in the load impedance at each point on the power amplifier circuit 100 is illustrated at left-side portions. The variations in the output power of the amplifiers in the amplifier circuit 105A are illustrated at upper right-side portions, and the variations in the output power of the amplifiers in the amplifier circuit 105C are illustrated at lower right-side portions.

In FIG. 9, in the case where the load impedance R_{ANT} of the antenna ANT exceeds the characteristic impedance R_{L} and is Hi, the output line 151 causes the load impedance at the connection node N3C to be Lo. As for the amplifier circuit 105A, the load impedance in the peaking amplifier 142A is Lo. The load impedance in the carrier amplifier 141A is Hi due to the phase shift line 135A.

As for the amplifiers, the output power decreases as the load impedance increases, and the output power increases as the load impedance decreases. For this reason, as for the amplifier circuit 105A, the output power of the carrier amplifier 141A decreases due to an increase in the load (a solid line LN11), and the output power of the peaking amplifier 142A increases due to a decrease in the load (a dashed line LN10) as in the case where the phase in a right-side graph is 0° to 90° or 270° to 360°. Consequently, power variations are canceled out due to the decrease in the output power of the carrier amplifier 141A and the increase in the output power of the peaking amplifier 142A. Accordingly, as for the amplifier circuit 105A, synthesized output power has flat characteristics as in a solid line LN12.

As for the amplifier circuit 105C, the load impedance in the amplifier 141C is Hi, and the load impedance in the amplifier 142C is Lo due to the phase shift line 131. For this reason, as for the amplifier circuit 105C, the output power of the amplifier 141C decreases due to the increase in the load (a dashed line LN15), and the output power of the amplifier 142C increases due to the decrease in the load (a solid line LN16). Consequently, the power variations are canceled out due to the decrease in the output power of the amplifier 141C and the increase in the output power of the amplifier 142C. Accordingly, as for the amplifier circuit 105C, synthesized output power has flat characteristics as in a solid line LN17.

That is, as for each of the amplifier circuits 105A and 105C, the variations in the output power due to the variation in the load impedance are consequently canceled out, and accordingly, the variation in the output power of the whole of the power amplifier circuit 100 is reduced. This enables the robustness due to the load variation of the antenna to be improved.

In the case where the load impedance R_{ANT} of the antenna ANT in FIG. 10 is less than the characteristic impedance R_{L}, the variation in the load impedance in the amplifiers in the amplifier circuits 105A and 105C is opposite that in the case of FIG. 9. That is, as for the amplifier circuit 105A, the output power of the carrier amplifier 141A increases (the solid line LN11), and the output power of the peaking amplifier 142A decreases (the dashed line LN10) as in the case where the phase in a right-side graph is 90° to 270°. As for the amplifier circuit 105C, the output power of the amplifier 141C increases (the dashed line LN15), and the output power of the amplifier 142C decreases (the solid line LN16). As for each of the amplifier circuits 105A and 105C, the variations in the output power due to the variation in the load impedance are consequently canceled out as in the case of FIG. 9. Accordingly, also in the case where the load impedance R_{ANT} of the antenna ANT is less than the characteristic impedance R_{L}, the variation in the output power of the whole of the power amplifier circuit 100 is reduced. This enables the robustness against the load variation of the antenna to be improved.

### (b) at 6 Db Backoff

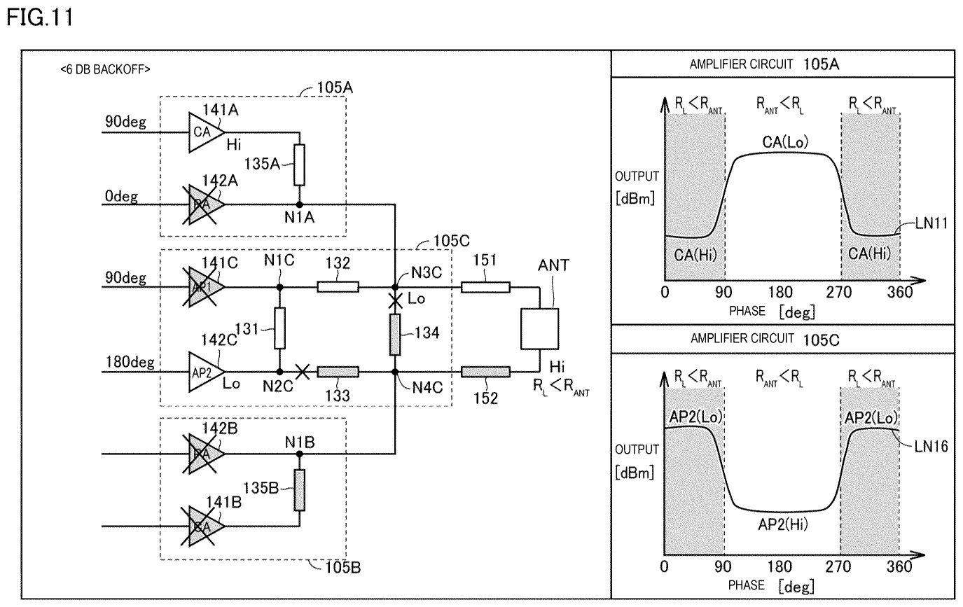

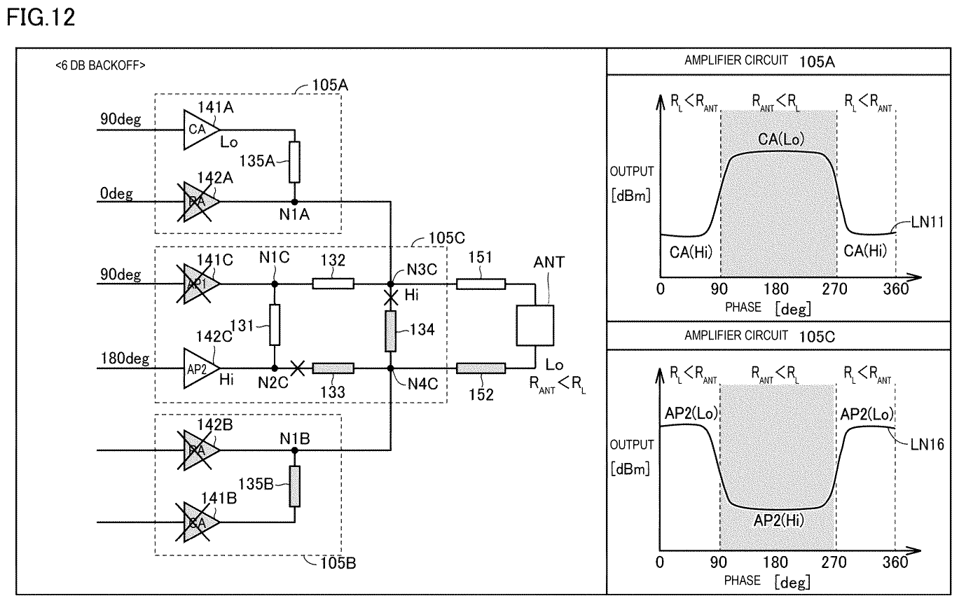

FIG. 11 and FIG. 12 are diagrams for describing the influence of the load variation at 6 dB backoff, that is, in the case where only the carrier amplifier 141A enters the drive state in the amplifier circuit 105A, and only the amplifier 142C enters the drive state in the amplifier circuit 105C. FIG. 11 is the diagram for describing the output state regarding the amplifiers in the case where the load impedance R_{ANT} of the antenna ANT exceeds the characteristic impedance R_{L} (R_{L}<R_{ANT}). FIG. 12 is the diagram for describing the output state regarding the amplifiers in the case where the load impedance R_{ANT} of the antenna ANT is less than the characteristic impedance R_{L} (R_{ANT}<R_{L}).

As for each of the amplifier circuits 105A and 105C, only a single amplifier is driven at the 6 dB backoff, and accordingly, the amplifier circuits 105A and 105C cannot cancel out output variations due to the load variation unlike FIG. 9 and FIG. 10.

However, the direction of the variation in the load impedance in the carrier amplifier 141A that is driven in the amplifier circuit 105A and the direction of the variation in the load impedance in the amplifier 142C that is driven in the amplifier circuit 105C are opposite each other. For this reason, as for a synthesized signal that is synthesized at the connection node N3C, a variation (the solid line LN11) in the output power in the carrier amplifier 141A and a variation (the solid line LN16) in the output power in the amplifier 142C are canceled out.

Accordingly, the variations in the output power are canceled out between the output signal of the amplifier circuit 105A and the output signal of the amplifier circuit 105C also at the 6 dB backoff, and accordingly, the robustness against the load variation of the antenna can be improved.

Only the carrier amplifier 141A in the amplifier circuit 105A is driven at 12 dB backoff, and accordingly, the variations in the output power due to the load variation of the antenna cannot be reduced.

As for the power amplifier circuit of the communication device, the amplifier circuits corresponding to the radio frequency signals in the two different frequency bands to be output are connected by using the hybrid coupler that is shared by the amplifier circuits for the two frequency bands, and consequently, the radio frequency signals in the two different frequency bands can be switched and output without using a switch, as described above.

In addition, the two amplifier circuits that are used for outputting a signal are included as Doherty amplifiers. Consequently, a backoff amount of 6 dB or more is achieved, and the robustness against the load variation of the antenna can be improved.

The “amplifier circuit 105A”, the “amplifier circuit 105C”, and the “amplifier circuit 105B” according to the first embodiment respectively correspond to a “first amplifier circuit”, a “second amplifier circuit”, and a “third amplifier circuit” according to the present disclosure. The “output terminal T1” and the “output terminal T2” according to the first embodiment respectively correspond to a “first output terminal” and a “second output terminal” according to the present disclosure. The “output line 151” and the “output line 152” according to the first embodiment respectively correspond to a “first output line” and a “second output line” according to the present disclosure. The “carrier amplifier 141A” and the “carrier amplifier 141B” according to the first embodiment respectively correspond to a “first carrier amplifier” and a “second carrier amplifier” according to the present disclosure. The “peaking amplifier 142A” and the “peaking amplifier 142B” according to the first embodiment respectively correspond to a “first peaking amplifier” and a “second peaking amplifier” according to the present disclosure. The “phase shift line 135A” and the “phase shift line 135B” according to the first embodiment respectively correspond to a “first phase shift line” and a “second phase shift line” according to the present disclosure. The “amplifier 141C” and the “amplifier 142C” according to the first embodiment respectively correspond to a “first amplifier” and a “second amplifier” according to the present disclosure. The “phase shift line 131” to the “phase shift line 134” according to the first embodiment correspond to a “first line” to a “fourth line” according to the present disclosure. The “connection node N1C” to the “connection node N4C” according to the first embodiment correspond to a “first connection node” to a “fourth connection node” according to the present disclosure.

### Second Embodiment

According to a second embodiment, structures different from those of the amplifier circuits 105A and 105B according to the first embodiment will be described.

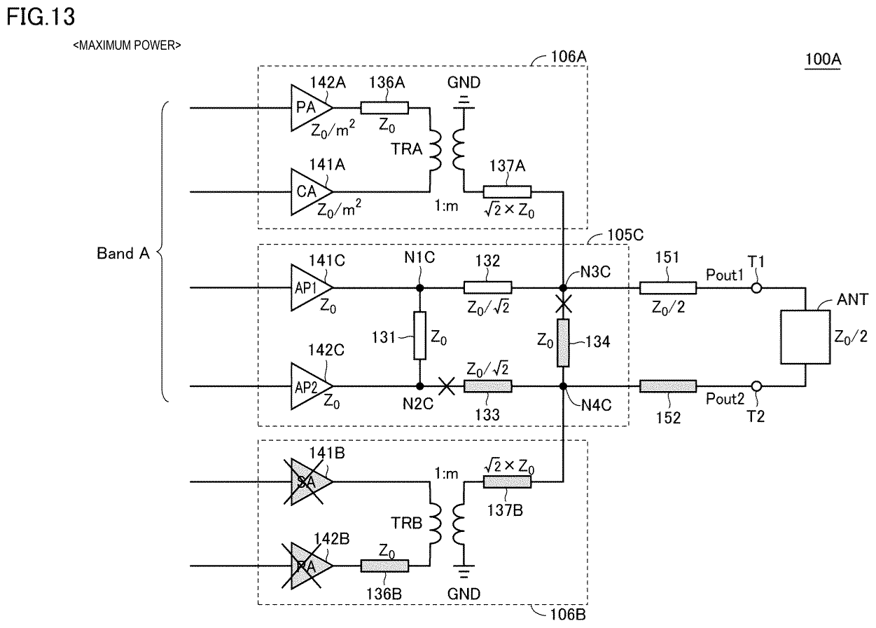

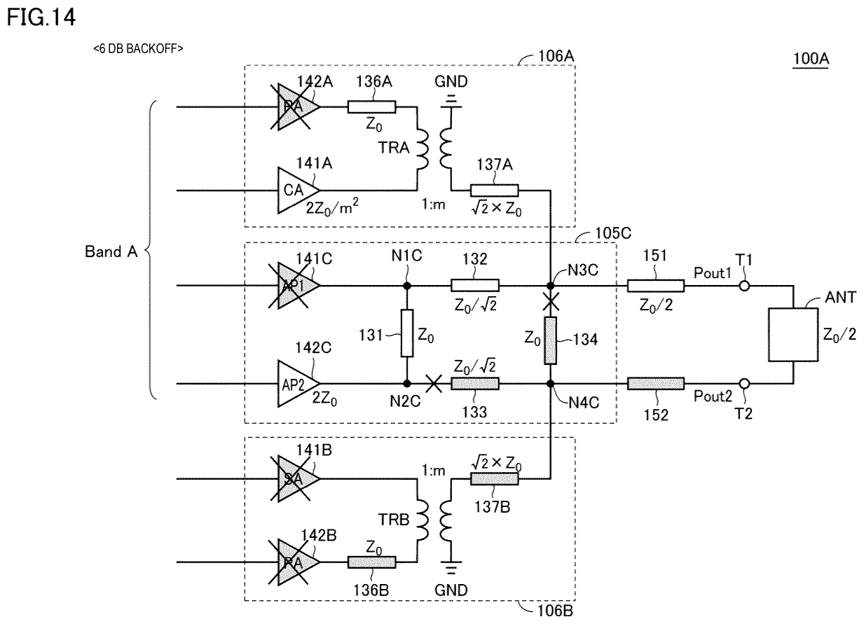

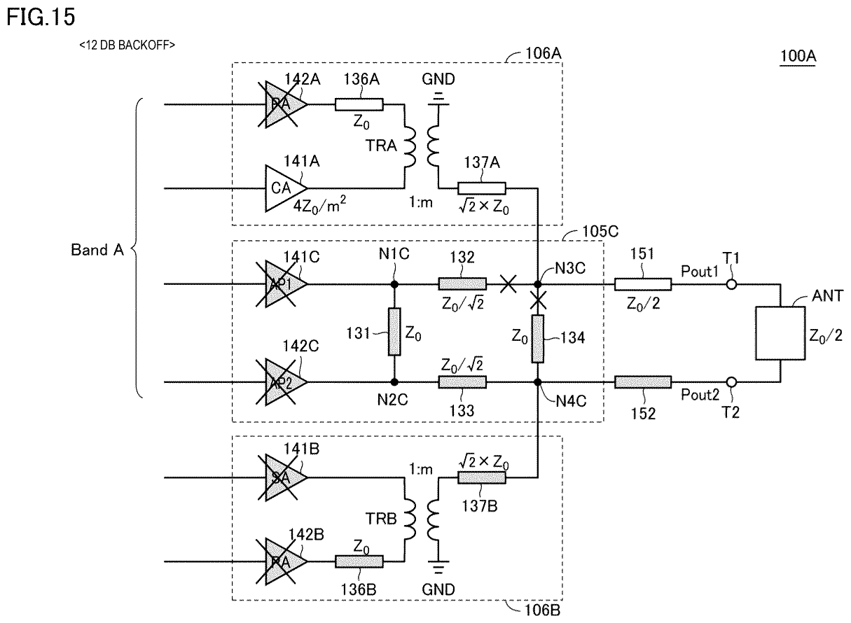

FIG. 13 to FIG. 15 are diagrams for describing the structure of a power amplifier circuit 100A that is used for a transmission circuit according to the second embodiment and the impedance of amplifiers at the maximum power output and at backoff. FIG. 13 illustrates a state at the maximum power output. FIG. 14 illustrates a state at the 6 dB backoff. FIG. 15 illustrates a state at the 12 dB backoff.

As for the power amplifier circuit 100A, the amplifier circuits 105A and 105B in the power amplifier circuit 100 according to the first embodiment are replaced with amplifier circuits 106A and 106B. In an example in the following description, a radio frequency signal in the band A is output from the output terminal T1.

Referring to FIG. 13, the amplifier circuit 106A includes a transformer TRA and phase shift lines 136A and 137A instead of the phase shift line 135A in the amplifier circuit 105A. Similarly, the amplifier circuit 106B includes a transformer TRB and phase shift lines 136B and 137B instead of the phase shift line 135B in the amplifier circuit 105B.

As for the transformer TRA in the amplifier circuit 106A, a winding ratio between a primary winding and a secondary winding is 1:m. A first end of the primary winding of the transformer TRA is connected to the output end of the carrier amplifier 141A. A second end of the primary winding is connected to the output end of the peaking amplifier 142A with the phase shift line 136A interposed therebetween.

A first end of the secondary winding of the transformer TRA is connected to the connection node N3C in the amplifier circuit 105C with the phase shift line 137A interposed therebetween. A second end of the secondary winding is connected to the ground potential GND.

As for the transformer TRB in the amplifier circuit 106B, a winding ratio between a primary winding and a secondary winding is 1:m. A first end of the primary winding of the transformer TRB is connected to the output end of the carrier amplifier 141B. A second end of the primary winding is connected to the output end of the peaking amplifier 142B with the phase shift line 136B interposed therebetween.

A first end of the secondary winding of the transformer TRB is connected to the connection node N4C in the amplifier circuit 105C with the phase shift line 137B interposed therebetween. A second end of the secondary winding is connected to the ground potential GND.

The phase shift lines 136A and 137A have the electrical length corresponding to the quarter wavelength of the center frequency of the frequency band of the band A. The phase shift lines 136B and 137B have the electrical length corresponding to the quarter wavelength of the center frequency of the frequency band of the band B. In the case where the impedance of the antenna ANT is Z₀/2, the impedance of the phase shift lines 136A and 136B is set at Z₀, and the impedance of the phase shift lines 137A and 137B is set at (√2)×Z₀.

As for the power amplifier circuit 100A, the amplifier circuit 106A and the amplifier circuit 106B are connected to the amplifier circuit 105C by using the transformers TRA and TRB. As for the amplifier circuit 106A and the amplifier circuit 106B, the output signals of Doherty amplifiers that include carrier amplifiers and peaking amplifiers are consequently synthesized regarding voltage toward the amplifier circuit 105C.

In the case where a radio frequency signal from the band A is output at maximum power as in FIG. 13, the amplifiers that are included in the amplifier circuits 106A and 105C enter the drive state, and the amplifier circuit 106B enters the non-drive state. At this time, impedance when the load is viewed from output ends of the carrier amplifier 141A and the peaking amplifier 142A in the amplifier circuit 106A is Z₀/m². Impedance when the load is viewed from output ends of the amplifiers 141C and 142C in the amplifier circuit 105C is Z₀.

In the case of the 6 dB backoff in FIG. 14, the peaking amplifier 142A of the amplifier circuit 106A and the amplifier 141C of the amplifier circuit 105C enter the non-drive state. Consequently, the impedance when the load is viewed from the output end of the carrier amplifier 141A in the amplifier circuit 106A is 2Z₀/m². The impedance when the load is viewed from the output end of the amplifier 142C in the amplifier circuit 105C is 2Z₀. That is, as for the amplifier circuit 106A and the amplifier circuit 105C, the number of the amplifiers to be used is halved, and the impedance of the carrier amplifier 141A and the amplifier 142C to be used is doubled unlike the case of FIG. 13, and accordingly, a backoff amount of 6 dB can be achieved.

In the case of the 12 dB backoff in FIG. 15, the peaking amplifier 142A of the amplifier circuit 106A enters the non-drive state, and the amplifier circuits 105C and 106B enter the non-drive state. In other words, as for the power amplifier circuit 100A, only the amplifier 141C of the amplifier circuit 106A enters the drive state. In this case, the impedance when the load is viewed from the output end of the carrier amplifier 141A is 4Z₀/m². The impedance corresponds to twice the impedance in the case of FIG. 14 and to four times the impedance in the case of FIG. 13. That is, as for the amplifier circuit 106A, the number of the amplifiers to be used is halved, and the impedance of the amplifiers to be driven is doubled unlike the case of FIG. 14. This enables a backoff amount of 6 dB to be additionally achieved and enables a backoff amount of 12 dB to be achieved unlike the case of FIG. 13.

### Third Embodiment

Although the first embodiment and the second embodiment have a dual-band structure in which radio frequency signals in two different frequency bands are output, features according to the present disclosure can be used for a single-band structure in which a radio frequency signal in a single frequency band is output.

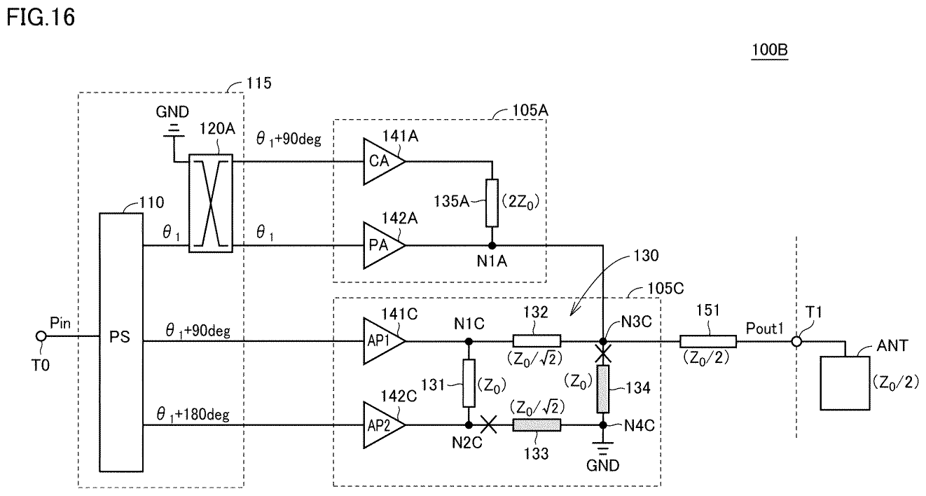

FIG. 16 illustrates the structure of a power amplifier circuit 100B that is used for a transmission circuit according to a third embodiment. The power amplifier circuit 100B has a structure acquired by removing a circuit corresponding to the band B in the power amplifier circuit 100 according to the first embodiment illustrated in FIG. 2. Specifically, the output line 152, the amplifier circuit 105B, and the hybrid coupler 120B in the branch circuit 115 are removed. The connection node N4C in the hybrid coupler 130 of the amplifier circuit 105C is connected to the ground potential GND. This is equivalent to the structure illustrated in FIG. 3.

Also as for the power amplifier circuit 100B, the power supply voltage Vcc is switched depending on the power level of the input signal Pin, a backoff amount of 12 dB is achieved by switching the drive states of the amplifiers 141C and 142C in the amplifier circuit 105C and the peaking amplifier 142A of the amplifier circuit 105A as described with reference to FIG. 7 and FIG. 8, and the robustness against the load variation of the antenna ANT can be improved.

The functionality of the elements disclosed herein—including the baseband processing, digital envelope tracking, selection signal generation, and dynamic bias adjustment of the amplifier circuits—may be implemented using circuitry (also referred to herein as processing circuitry). As used herein, circuitry encompasses both programmable circuitry and fixed circuitry, or combinations thereof. Programmable circuitry includes one or more general-purpose processors, digital signal processors, microcontrollers, or FPGAs (Field Programmable Gate Arrays) programmed using instructions stored in one or more non-transitory computer-readable memories. Fixed circuitry includes one or more ASICs (Application Specific Integrated Circuits), hardwired logic circuits, or other non-programmable circuit structures. The bias control circuit 50 (also referred to herein as control circuitry) may be implemented as programmable circuitry, fixed circuitry, or a combination thereof. The selective enabling and disabling of the carrier amplifiers and peaking amplifiers in response to changes in the power level of the input signal represents a concrete physical transformation of the operating state of the hardware—specifically, a dynamic reconfiguration of load impedance presented to each active amplifier—that produces a measurable improvement in amplification efficiency across a range of output power levels.

It is to be thought that the embodiments disclosed herein are examples in all aspects and are not restrictive. The scope of the present disclosure is not shown by the above description of the embodiments but is shown by claims and includes meanings equivalent to those of the claims and all modifications within the scope.

### REFERENCE SIGNS LIST

1 communication device, 10 transmission circuit, 20 BBIC, 30 RFIC, 40 power supply circuit, 50 bias control circuit, 100, 100A, 100B power amplifier circuit, 105A to 105C, 106A, 106B amplifier circuit, 110 phase shift circuit, 115 branch circuit, 120A, 120B, 130 hybrid coupler, 131 to 134, 135A, 135B, 136A, 136B, 137A, 137B phase shift line, 141A, 141B carrier amplifier, 141C, 142C amplifier, 142A, 142B peaking amplifier, 151, 152 output line, 410 MPC, 420 power supply selection circuit, 430 digital ET, ANT antenna, GND ground potential, N1A, N1B, N1C to N4C connection node, SP1, SP2 feed point, T0, T3, T4 input terminal, T1, T2 output terminal, TRA, TRB transformer, VB battery voltage, Vcc power supply voltage.

1. A transmission circuit, comprising:
an input terminal configured to receive a radio frequency signal;
a first output terminal for connection to a radiating element;
a first amplifier circuit and a second amplifier circuit configured to amplify the radio frequency signal received by the input terminal;
a first output line configured to transmit an output signal from the first amplifier circuit to the first output terminal,
wherein the first amplifier circuit is a Doherty amplifier that includes a first carrier amplifier, a first peaking amplifier, and a first phase shift line that is connected between an output end of the first carrier amplifier and an output end of the first peaking amplifier,
wherein the second amplifier circuit includes a first amplifier, a second amplifier, and a hybrid coupler,
wherein the hybrid coupler includes a first line, a second line, a third line, and a fourth line that are connected in an annular shape,
wherein an output end of the first amplifier is connected to a first connection node between the first line and the second line,
wherein an output end of the second amplifier is connected to a second connection node between the first line and the third line, and
wherein the output end of the first peaking amplifier and the first output line are connected to a third connection node between the second line and the fourth line; and
control circuitry configured to selectively switch drive states of the first peaking amplifier, the first amplifier, and the second amplifier based on a power level of the radio frequency signal received at the input terminal.

2. The transmission circuit according to claim 1, further comprising:
a second output terminal;
a third amplifier circuit; and
a second output line through which an output signal from the third amplifier circuit is transmitted to the second output terminal,
wherein the third amplifier circuit is a Doherty amplifier that includes a second carrier amplifier, a second peaking amplifier, and a second phase shift line that is connected between an output end of the second carrier amplifier and an output end of the second peaking amplifier,
wherein the output end of the second peaking amplifier and the second output line are connected to a fourth connection node between the third line and the fourth line, and
wherein the control circuitry is configured to selectively switch a drive state of the second peaking amplifier, and the drive states of the first amplifier and the second amplifier based on the power level of the radio frequency signal received at the input terminal.

3. The transmission circuit according to claim 2, wherein the radiating element is configured to radiate a radio wave corresponding to two radio frequency signals in different frequency bands,
wherein, in a case where a radio wave corresponding to a radio frequency signal in a first frequency band is radiated, the control circuitry is configured to supply the radio frequency signal in the first frequency band to the first amplifier circuit and the second amplifier circuit, and to not drive the third amplifier circuit, and
wherein in a case where a radio wave corresponding to a radio frequency signal in a second frequency band is radiated, the control circuitry is configured to supply the radio frequency signal in the second frequency band to the second amplifier circuit and the third amplifier circuit, and to not drive the first amplifier circuit.

4. The transmission circuit according to claim 3, further comprising:
a branch circuit configured to branch the radio frequency signal received by the input terminal into the amplifier circuits,
wherein, in a case where a radio wave in the first frequency band is radiated, the branch circuit is configured to supply, to the first carrier amplifier and the first amplifier, a signal that has a phase shifted by 90° relative to a signal that is supplied to the first peaking amplifier, and supplies, to the second amplifier, a signal that has a phase shifted by 180° relative to the signal supplied to the first peaking amplifier, and
wherein, in a case where a radio wave in the second frequency band is radiated, the branch circuit is configured to supply, to the second carrier amplifier and the second amplifier, a signal that has a phase shifted by 90° relative to a signal that is supplied to the second peaking amplifier, and supplies, to the first amplifier, a signal that has a phase shifted by 180° relative to the signal supplied to the second peaking amplifier.

5. The transmission circuit according to claim 4, wherein in the case where the radio wave in the first frequency band is radiated, if the power level of the input signal is equal to or more than a first threshold, the control circuitry is configured to drive the first carrier amplifier, the first peaking amplifier, the first amplifier, and the second amplifier, and if the power level of the input signal is less than the first threshold and is equal to or more than a second threshold, the control circuitry is configured to drive the first carrier amplifier and the second amplifier, and to not drive the first peaking amplifier and the first amplifier.

6. The transmission circuit according to claim 5, wherein, in the case where the radio wave in the first frequency band is radiated, if the power level of the input signal is less than the second threshold, the control circuitry is configured to drive the first carrier amplifier is driven, and the first peaking amplifier, the first amplifier, and to not drive the second amplifier.

7. The transmission circuit according to claim 4, wherein in the case where the radio wave in the second frequency band is radiated, if the power level of the input signal is equal to or more than a first threshold, the second carrier amplifier, the control circuitry is configured to drive the second peaking amplifier, the first amplifier, and the second amplifier, and if the power level of the input signal is less than the first threshold and is equal to or more than a second threshold, the control circuitry is configured to drive the second carrier amplifier and the first amplifier, and to not drive the second peaking amplifier and the second amplifier.

8. The transmission circuit according to claim 7, wherein in the case where the radio wave in the second frequency band is radiated, if the power level of the input signal is less than the second threshold, the control circuitry is configured to drive the second carrier amplifier is driven, and to not drive the second peaking amplifier, the first amplifier, and the second amplifier.

9. The transmission circuit according to claim 1, wherein each of the first, second, third, and fourth lines of the hybrid coupler has an electrical length corresponding to a quarter wavelength of a center frequency of the radio frequency signal.

10. The transmission circuit according to claim 1, wherein the first phase shift line has an electrical length corresponding to a quarter wavelength of a center frequency of the radio frequency signal amplified by the first amplifier circuit.

11. The transmission circuit according to claim 1, further comprising a power supply circuit configured to supply a power supply voltage to the first amplifier circuit and the second amplifier circuit at a plurality of discrete voltage levels, wherein the power supply circuit selects the power supply voltage based on an envelope of the radio frequency signal.

12. The transmission circuit according to claim 11, wherein the power supply circuit is configured to supply the power supply voltage at a first voltage level when the first carrier amplifier, the first peaking amplifier, the first amplifier, and the second amplifier are all active, at a second voltage level lower than the first voltage level when only the first carrier amplifier and the second amplifier are active and the first peaking amplifier and the first amplifier are inactive, and at a third voltage level lower than the second voltage level when only the first carrier amplifier is active.

13. The transmission circuit according to claim 1, wherein the first phase shift line has an impedance of 2Z₀ and the first output line has an impedance of Z₀/2, where Z₀/2 is a load impedance of the radiating element.

14. The transmission circuit according to claim 13, wherein the control circuitry is further configured to
additionally remove bias current from the second amplifier while continuing to supply bias current to only the first carrier amplifier; and
remove bias current from the second amplifier and the first amplifier while supplying bias current to only the first carrier amplifier when the power level of the radio frequency signal falls below a second threshold lower than the first threshold.

15. The transmission circuit according to claim 1, wherein the first line and the fourth line of the hybrid coupler each have an impedance of Z₀, and the second line and the third line each have an impedance of Z₀/√2, where Z₀ is a characteristic impedance of the first output line.

16. The transmission circuit according to claim 1, wherein the first amplifier circuit further includes a transformer having a primary winding and a secondary winding with a winding ratio of 1:m, a first end of the primary winding connected to the output end of the first carrier amplifier, a second end of the primary winding connected to the output end of the first peaking amplifier, a first end of the secondary winding connected to the third connection node, and a second end of the secondary winding connected to a ground potential.

17. The transmission circuit according to claim 1, wherein the first amplifier and the second amplifier of the second amplifier circuit each have a transistor size that is smaller than a transistor size of the first carrier amplifier and the first peaking amplifier of the first amplifier circuit.

18. A communication device comprising:
the transmission circuit according to claim 1;
a signal processing circuit that processes a radio frequency signal to be supplied to the transmission circuit; and
the radiating element that radiates, as a radio wave, a radio frequency signal that is amplified by the transmission circuit.
